(19) United States
(12) Patent Application Publication
(10) Pub. No.: US 2025/0048690 A1
(43) Pub. Date: Feb. 6, 2025

(54) A COMPLEMENTARY FIELD-EFFECT TRANSISTOR DEVICE

(71) Applicants: IMEC VZW, Leuven (BE); Huawei Technologies Co., Ltd., Shenzhen, Guangdong (CN)

(72) Inventors: Bilal CHEHAB, Leuven (BE); Krishna Kumar BHUWALKA, Heverlee (BE); Julien RYCKAERT, Schaerbeek (BE)

(21) Appl. No.: 18/715,354

(22) PCT Filed: Dec. 2, 2021
(86) PCT No.: PCT/EP2021/083980

§ 371 Date: May 31, 2024

(51) Int. Cl. H01L 29/06; H01L 27/092; H01L 29/423; H01L 29/775; H01L 29/786

(52) U.S. Cl. CPC H01L 29/0673; H01L 27/092; H01L 29/42392; H01L 29/775; H01L 29/78696

(57) ABSTRACT

The disclosure relates to a CFET device (100) comprising: a bottom FET device (130) and a top FET device (140) stacked on top of the bottom FET device (130), the bottom FET device (130) comprising a bottom channel nanostructure (132) and a bottom gate electrode (134) comprising a side gate portion (134a) arranged along a first side surface (132a) of the bottom channel nano structure, and the top FET device (140) comprising a top channel nanosheet (142) and a top gate electrode (144) configured to define a tri-gate with respect to the top channel nanosheet and comprising a side gate portion (144b) arranged along a second side surface (142b) of the top channel nanosheet, wherein the side gate portion (134a) of the bottom gate electrode (134) defines a via contact portion protruding outside the top gate electrode (144) and the first side surface (142a) of the top channel nanosheet (142); and atop gate contact via (146) for coupling the top gate electrode (144) to a first conductive line (124) over the top FET device (140) and a bottom gate contact via (136) for coupling the via contact portion (134a) of the bottom gate electrode (134) to a second conductive line (128) over the top FET device (140).

### TECHNICAL FIELD

The present disclosure relates to a Complementary Field-Effect Transistor (CFET) device.

### BACKGROUND

Modern semiconductor device processing involves designing integrated circuits comprising a great number of standardized unit cells (“standard cells”) comprising a combination of active devices, such as transistors. Intra- and inter-cell signal routing between active devices may be provided by an interconnect structure comprising e.g. a set of conductive lines and vias. Standard cells may be designed to provide certain functionality, logic functions, storage functions or the like. In standard cell methodology, the designer may accordingly combine cells from a library of standard cells to design a circuit with desired functions.

The metal lines of an interconnect structure for a standard cell may be formed along a respective one of a set of parallel “routing tracks”, typically having a uniform width and pitch.

As integrated circuits continue to become smaller and smaller and simultaneously comprise an increasing number of semiconductor devices within a given area, there is a strive for reducing the size of the standard cells, among others by reducing the “track height” of the cell, i.e. the number of routing tracks per cell.

In the Complementary Field-Effect Transistor (CFET) device a complementary pair of FETs are stacked on top of each other (e.g. an NMOS device stacked on top of a PMOS device). The CFET allows a reduced footprint compared to a traditional side-by-side arrangement of a pFET and nFET. The two device levels provided by the CFET (e.g. a “2-level middle-of line/MOL”) further enables a reduced routing layer usage (e.g. in the back-end-of line/BEOL). The CFET hence facilitates realization of low track height cells such as 4-track (4T) cells.

A CFET device may be formed using a monolithic approach and a sequential approach. A “monolithic CFET” may comprise a gate electrode which is physically and electrically common (i.e. a monolithic gate electrode) to the top and bottom device. Meanwhile, a “sequential CFET” allows separate gate electrodes for the top and bottom devices.

### SUMMARY

According to first aspect of the present inventive concept there is provided complementary field-effect transistor, CFET, device comprising:
a bottom FET device and a top FET device stacked on top of the bottom FET device,
   the bottom FET device comprising a bottom channel nanostructure having a first side surface oriented in a first direction and a second side surface oriented in a second direction opposite the first direction, and a bottom gate electrode configured to define a tri-gate or a gate-all-around with respect to the bottom channel nanostructure, the bottom gate electrode comprising a side gate portion arranged along the first side surface of the bottom channel nanostructure, and
   the top FET device comprising a top channel nanosheet having a first side surface oriented in the first direction and a second side surface oriented in the second direction, and a top gate electrode configured to define a tri-gate with respect to the top channel nanosheet and comprising an upper gate portion, a lower gate portion and a side gate portion arranged along the second side surface of the top channel nanosheet,
   wherein the side gate portion of the bottom gate electrode defines a via contact portion protruding outside the top gate electrode and the first side surface of the top channel nanosheet; and
a top gate contact via for coupling the top gate electrode to a first conductive line over the top FET device and a bottom gate contact via for coupling the via contact portion of the bottom gate electrode to a second conductive line over the top FET device.

The CFET device according to the first aspect facilitates an independent contacting of the top and bottom gate electrodes, i.e. an independent gate pick-up. In particular, by the tri-gate configuration of the top gate electrode the via contact portion may protrude outside, i.e. with respect to, the top FET device, along the first direction, such that access to the via contact portion by the top gate contact via is allowed with minor or no area penalty. A risk of shorting between the top gate electrode and the bottom gate contact via may thus be mitigated.

As used herein, the term “gate-all-around” refers to a gate electrode extending to completely surround the channel structure. Accordingly, a gate-all-around configuration of the bottom gate electrode with respect to the bottom channel nanostructure implies that the bottom gate electrode extends along the first side surface, an upper surface, a lower surface and the second side surface of the bottom channel nanostructure.

As used herein, the term “tri-gate” refers to a gate electrode extending along exactly three surfaces of a channel structure (e.g. the top channel nanosheet or the bottom channel nanostructure). Accordingly, the tri-gate configuration of the top gate electrode with respect to the top channel nanosheet implies that the top gate electrode extends along the second side surface of the top channel nanosheet, and along an upper surface and a lower surface of the channel nanosheet, but not along the first side surface of the top channel nanosheet.

The tri-gate configuration of the top gate electrode with respect to the top channel nanosheet thus enables a zero gate extension at the first side surface of the top channel nanosheet, which creates a space for the bottom gate contact via. In other words, the first side surface of the top channel nanosheet may define a non-gated side surface.

Since the top FET device comprises a channel structure in the shape of a nanosheet, a satisfactory level of channel control may be enabled despite the zero gate extension at the first side surface. Additionally, the combination of using a nanosheet as channel structure and the tri-gate configuration enables an increased channel width compared to a gate-all around configuration, assuming gate electrodes of equal width, and hence an increased drive current.

The CFET device of the first aspect confers a design flexibility in terms of type of bottom device, which as will be further described below e.g. may be either be of a fin-based or a nanosheet-based FET.

The merits of the CFET device of the first aspect may be especially useful in low track height cell implementations and at aggressive line pitches, wherein the space available for the top gate contact via tends to be limited. It is however envisaged that the CFET device may be used in any context wherein a CFET device with independent top and bottom gate pick-up is needed.

Relative spatial terms such as “top”, “bottom”, “upper”, “lower”, “vertical”, “stacked on top of”, “alongside” and “horizontal” are used to refer to locations or directions within a frame of reference of the CFET device. In particular, “top”, “bottom”, “upper”, “lower”, “vertical” and “stacked on top of” may be understood in relation to a bottom-up direction of the CFET device (i.e. a direction from the bottom FET device towards the top FET device), or equivalently a normal direction to a substrate of the CFET device, in particular a main plane of extension of the substrate. Correspondingly, the terms “alongside”, “horizontal” and “lateral” may be understood as positions or orientations as viewed along a direction parallel to (the main plane of extension of) the substrate.

As used herein, the term “CFET” refers to a device comprising a bottom FET device of a first conductivity type and a top FET device of a second opposite conductive type stacked on top of the bottom FET device, e.g. an n-type MOSFET (NMOSFET) stacked on top of a p-type MOSFET (PMOSFET) or vice versa. The top FET device may more specifically be arranged directly above the bottom FET device.

The wording a first structure arranged “directly above” a second structure as used herein refers to a relative positioning of the first and second structures such that the first structure at least partly overlaps the second structure as viewed along the vertical (e.g. bottom-up) direction. Correspondingly, the wording a first structure arranged “directly underneath” a second structure as used herein refers to a relative positioning of the first and second structures such that the second structure at least partly overlaps the first structure as viewed along the vertical (e.g. bottom-up) direction.

As used herein, the term “nanosheet” refers to a nanostructure having a width to thickness ratio greater than 1, e.g. 2 or greater. “Nanosheet” is in particular used to refer to a horizontally oriented nanosheet, e.g. parallel to a substrate of the CFET device.

According to some embodiments, the CFET device may further comprise a dielectric layer arranged between the bottom gate electrode and the top gate electrode, wherein the bottom gate contact via extends through the dielectric layer.

The top gate electrode and bottom gate electrode may thus be physically and electrically spaced apart from each other by the dielectric layer. Meanwhile, the via contact portion allows the bottom gate contact via to couple the second conductive line to the bottom gate electrode, by-passing the top gate electrode arranged directly above the bottom gate electrode.

According to some embodiments, the top channel nanosheet may be arranged directly above the bottom channel nanostructure.

The top FET device may hence be stacked on top of the bottom FET device such that the top channel nanosheet at least partly overlaps the bottom channel nanostructure, as viewed along a vertical direction.

According to some embodiments, the first side surface of the bottom channel nanostructure may be aligned with the first side surface of the top channel nanosheet.

This further contributes to an area efficient design by minimizing an extension of the side gate portion/via contact portion of the bottom gate electrode along the first direction needed to provide clearance for the bottom gate contact via with respect to the top gate electrode.

According to some embodiments, the bottom channel nanostructure is a nanosheet.

Using a channel structure in the shape of a nanosheet also for the bottom FET device may enable an increased drive current and reduced height of the FET device. The nanosheet shape may further contribute to a uniform electric performance of the top and bottom device.

The bottom channel nanosheet and the top channel nanosheet may have a same width.

In particular, the first side surface of the bottom channel nanosheet may be aligned with the first side surface of the top channel nanosheet, and the second side surface of the bottom channel nanosheet may be aligned with the second side surface of the top channel nanosheet

The top and bottom channel nanosheets may hence provide active areas of similar size.

According to some embodiments, the bottom gate electrode may be configured to define a gate-all-around with respect to the bottom channel nanosheet.

This may further improve channel control for the bottom FET device.

According to some embodiments, the bottom channel nanostructure may be a first fin structure, and wherein the bottom gate electrode may extend across the first fin structure to define a tri-gate with respect to the first fin structure.

A fin-based bottom FET device may hence be combined with a nanosheet-based top FET device, the fin structure being surrounded by a gate electrode along three surfaces (e.g. a pair of side surfaces and an upper surface).

According to some embodiments, the bottom FET device may further comprise a second fin structure arranged alongside the first fin structure, and wherein the bottom gate electrode may extend across the first fin and second fin structures to define a tri-gate with respect to each of the first and second fin structures.

As a nanosheet may present a greater footprint than a fin structure, two or more fin structures may be accommodated in the bottom FET device without an increased track height. A greater number of fin structures may enable an increased drive current of the bottom FET device.

According to some embodiments, the top channel nanosheet may be arranged directly above the first and the second fin structure.

This further contributes to an area efficient design by minimizing an extension of the side gate portion of the bottom gate electrode along the first direction needed to provide clearance for the bottom gate contact via with respect to the top gate electrode.

According to a second aspect, there is provided a circuit cell comprising a CFET device according to the first aspect or any of the afore-mentioned embodiments or variations thereof; and
an interconnect layer arranged over the top FET device and comprising the first and the second conductive line,
wherein the first conductive line of the interconnect structure is arranged to extend along a first routing track of the circuit cell and the second conductive line of the interconnect structure is arranged to extend along a second routing track of the circuit cell, the first and second routing tracks extending in parallel along a third direction transverse to the first and second directions.

The circuit cell may in particular be a standard cell of a standard cell device, e.g. e.g. a logic cell or a memory cell.

According to some embodiments, the circuit cell may be a 4-track cell, wherein the second routing track may be an edge track, the first routing track may be located directly above the top gate electrode, and wherein the side gate portion of the bottom gate electrode may protrude in the first direction such that the via contact portion is positioned directly underneath the first edge track.

The CFET device of the first aspect may hence be used to realize a 4T cell with independent top and bottom gate pick-up while mitigating a risk for shorting between the top gate electrode and the bottom gate contact via.

According to some embodiments, the first routing track may be a non-edge track arranged directly above the bottom and top gate electrode.

Having the top gate pick-up from a non-edge track may allow a second edge track opposite the first edge track to be used e.g. for a source/drain contact via, as well as create a margin between the CFET device and an adjacent cell.

According to a third aspect, there is provided an integrated circuit comprising:
a plurality of first circuit cells each in accordance with the second aspect or any of the afore-mentioned embodiments or variations thereof; and
a plurality of second circuit cells each comprising a bottom FET device and a top FET device stacked on top of the bottom FET device, the bottom FET device comprising a bottom channel nanostructure and a bottom gate electrode configured to define a tri-gate or a gate-all-around with respect to the bottom channel nanostructure, and
the top FET device comprising a top channel nanostructure and a top gate electrode configured to define a tri-gate or a gate-all-around with respect to the top channel nanostructure,
a bottom gate contact via extending between the top gate electrode and the bottom gate electrode to couple the top gate electrode to the bottom gate electrode, and
a top gate contact via coupling the top gate electrode to a third conductive line.

This enables CFET based circuit cells with independent gate pick-up and electrically common gates to be combined in a same integrated circuit. As may be appreciated, the circuit cells of the first and the second type may each be 4T standard cells, e.g. implementing different functionality.

### BRIEF DESCRIPTION OF THE DRAWINGS

The above, as well as additional objects, features and advantages, may be better understood through the following illustrative and non-limiting detailed description, with reference to the appended drawings. In the drawings like reference numerals will be used for like elements unless stated otherwise.

FIGS. 1a-d schematically illustrate a comparative example of a circuit cell comprising a CFET device.

FIGS. 2a-b schematically illustrate a CFET device according to an embodiment.

FIG. 3 schematically illustrates a CFET device according to a further embodiment.

FIGS. 4a-d schematically illustrate a circuit cell comprising a CFET device according to an embodiment.

FIG. 5 schematically illustrates an integrated circuit according to an embodiment.

### DETAILED DESCRIPTION

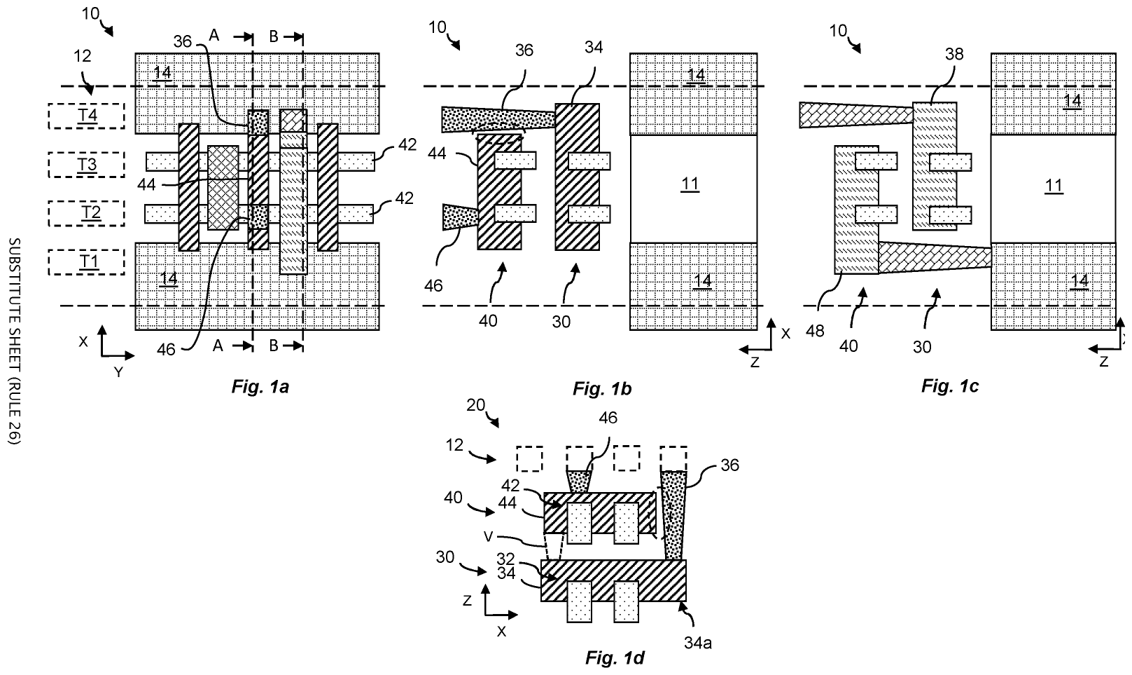

FIGS. 1a-d are provided by way of a comparative example and it is to be noted that the circuit cell 10 as shown therein is not intended as a representation of prior art. Rather, these figures are provided by way of example to illustrate certain design challenges in integrated circuit design based on CFETs, to thereby further elucidate the merits of a CFET device in accordance with the present inventive concept.

FIG. 1a is a schematic top-view of a circuit cell 10. FIGS. 1b and 1c are cross-sectional views of the circuit cell 10 along the plane A and B respectively, as indicated in FIG. 1a. FIGS. 1b and 1c are oriented sideways to facilitate association with the corresponding elements in FIG. 1a. FIG. 1d shows a part of the circuit cell 10 along the same plane as FIG. 1b in a normal or bottom-up orientation. Axes X and Y indicate a pair of transverse horizontal directions and axis Z indicates a vertical direction.

The circuit cell 10 comprises a CFET device 20 comprising a bottom device 30 (e.g. a PMOSFET) and a top device 40 (e.g. an NMOSFET). The bottom device 30 and the top device 40 each comprise a pair of channel nanostructures in the shape of a pair of fins 32 and 42 extending in parallel along direction Y.

The bottom device 30 comprises a bottom gate electrode 34 extending across the fins 32 in the X direction to define a tri-gate with respect to each of the fins 32. Correspondingly, the top device 40 comprises a bottom gate electrode 44 extending across the fins 42 to define a tri-gate with respect to each of the fins 42. The bottom and top device 30, 40 with physically separate bottom and top gate electrodes 34, 44 may be formed using a sequential process. The CFET device 20 may in other words form a sequential CFET device 20.

The cell 10 is a 4T cell comprising four routing tracks 12 uniformly spaced apart along direction X and extending in parallel along direction Y. The pitch of the routing tracks 12 substantially corresponds to the pitch of the fins 32, 42. The dashed lines extending in the Y direction represent boundaries of the cell 10, along the cell height direction X.

As shown in FIG. 1c, the source/drains 48 of the top device 40 may be tapped to a buried power rail 14 while the source/drains 38 of the bottom device 30 may be tapped to a metal line of one of the routing tracks 12.

The two contact levels (2-level MOL) provided by the CFET device 20 enables a reduced routing layer usage and the CFET device 20 is hence an enabler for low track height cells, in particular 4T cells. A considerable number of standard cells of a 4T standard cell library may be constructed based on a CFET device having electrically common top and gate electrodes. In a sequential CFET device, like the CFET device 20, electrically common top and gate electrodes may be provided by means of a short gate-to-gate via, schematically indicated with dashed outline V in FIG. 1d. However, some standard cells, in particular sequential cells including a tri-state/transmission-gate subcircuit may require electrically independent gates of the bottom and top device 30, 40 to avoid an area penalty. As highlighted in the dashed encircled region of FIGS. 1b and 1d, a separate coupling via 36 to the bottom gate electrode 34 may however be challenging to realize due to the presence of the top gate electrode 34 overlapping the bottom gate electrode 32. Further, there may not be space available to extend a side gate portion 34a of the bottom gate electrode 34 along direction X sufficiently to allow a via 36 to couple to the bottom gate electrode 34 without shorting with a side gate portion of the top gate electrode 44. As may be appreciated, this issue may be especially pronounced in low track height cells and at aggressive line pitches. An option could be to reduce the number of fins 42 in the top device 40, to allow a side gate portion with a smaller extension (along direction X). However, this would come at a cost of degraded performance of the top device 40.

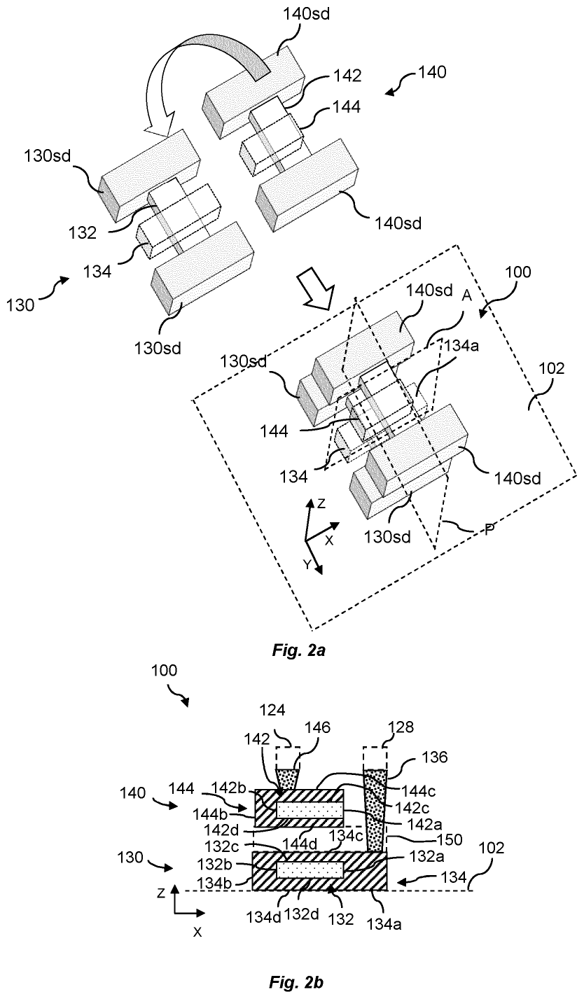

Embodiments of a CFET device 100 will now be described with reference to FIGS. 2a-b. In the figures axes X, Y and Z indicate a set of mutually transverse directions relative to a frame of reference of the device 100. Direction X denotes a first horizontal direction, Y denotes a third horizontal direction and Z denotes a vertical direction (e.g. corresponding to a bottom-up direction of the CFET device 100). The negative X direction (−X) denotes a second horizontal direction. FIG. 2a shows conceptual perspective views of the CFET device 100 and FIG. 2b illustrates a cross-sectional view of the CFET device 100 taken along a vertical plane A indicated in FIG. 2a (parallel to the XZ-plane).

The CFET device 100 comprises a bottom FET device 130 and a top FET device 140. The bottom FET device 130 and the top FET device 140 may in the following for brevity be denoted bottom device 130 and top device 140, respectively. As conceptually depicted in FIG. 2a, the top device 140 is stacked on top of the bottom device 130. The bottom device 130 defines a bottom level or bottom tier of the CFET device 100 and the top device 140 defines a top level or top tier of the CFET device 100. The bottom device 130 may e.g. be a p-type FET and the top device 140 may be an n-type FET, or vice versa. The bottom device 130 and the top device 140 may be separated from each other by a dielectric layer 150, as schematically indicated in FIG. 2b arranged intermediate the bottom and top device 130, 140.

The CFET device 102 may as shown be arranged on a substrate 102. The substrate 102 may be a semiconductor substrate, i.e. a substrate comprising at least one semiconductor layer, e.g. of Si, SiGe or Ge. The substrate 102 may be a single-layered semiconductor substrate, for instance formed by a bulk substrate. A multi-layered/composite substrate 102 is however also possible, such as an epitaxially grown semiconductor layer on a bulk substrate, or a semiconductor-on-insulator (SOI) substrate.

The bottom device 130 comprises a bottom channel nanostructure in the form of a nanosheet 132 and a bottom gate electrode 134. The top device 140 comprises a top channel nanostructure in the form of a nanosheet 142 and a top gate electrode 144. The bottom channel nanosheet 132 extends in the Y direction between a source and a drain region (commonly referenced first and second source/drain regions 130sd) of the bottom device 130, located on opposite sides of the bottom gate electrode 134. The top channel nanosheet 142 extends in the Y direction between a source and a drain region (commonly referenced first and second source/drain regions 140sd) of the top device 130, located on opposite sides of the top gate electrode 144.

The top device 140 is stacked on top of the bottom device 130 such that the first source/drain region 140sd of the top device 140 is arranged directly above the first source/drain region 130sd of the bottom device 130, and the second source/drain regions 140sd of the top device 140 is arranged directly above the second source/drain region 130sd of the bottom device 130. The bottom and top devices 130, 140 are as shown aligned with respect to each other such that the bottom channel nanostructure 132, the source and drain regions 130sd, the bottom gate electrode 134, the top channel nanosheet 142, the source and drain regions 140sd and the top gate electrode 144 intersect a common (geometrical) vertical plane P.

The nanosheets 132, 142 of the bottom and top devices 130, 140 may be formed of a semiconductor material such as group IV semiconductors, e.g. Si, Ge, SiGe. However also other materials are possible such as group III-V (e.g. InP, InAs, GaAs, GaN) semiconductors. The source/drain regions 130sd, 140sd may comprise doped semiconductor material (e.g. Si, Ge, SiGe), e.g. epitaxially grown on the nanosheets 132, 142 or formed by doped portions of the nanosheets 132, 142. The source/drain regions 130sd, 140sd may further comprise electrode material, e.g. deposited on the doped semiconductor material. Example electrode materials include conventional barrier metals such as Ta, TiN or TaN, and conventional fill metals such as W, Al, Ru, Mo or Co.

The bottom and top gate electrodes 134, 144 of the bottom and top devices 130, 140 may be formed of metal. Example metals include one or more gate work function metal (WFM) layers and/or a gate electrode fill layer. Example gate WFMs include conventional n-type and p-type effect WFM metals, such as TiN, TaN, TiAl, TiAlC or WCN, or combinations thereof. Example gate fill materials include W and Al. A gate dielectric layer (not shown) may be provided on the top and bottom nanosheets 132, 142, between the respective nanosheet 132, 142 and gate electrode 134, 144. Example gate dielectrics include conventional gate dielectrics, e.g. of a high-k such as HfO₂, LaO, AlO and ZrO.

The bottom channel nanosheet 132 of the bottom device 130 is horizontally oriented, i.e. parallel to the substrate 102. The nanosheet 132 has a first side surface 132a oriented in a first horizontal direction (e.g. the X direction) and a second side surface 132b oriented in the opposite second horizontal direction (e.g. the −X direction). The nanosheet 132 further has an upper surface 132c oriented in an upward direction (e.g. the Z direction) and a lower surface 132d oriented in a downward direction (e.g. the −Z direction).

The bottom gate electrode 134 is configured to define a gate-all-around (GAA) with respect to the nanosheet 132. The bottom gate electrode 134 comprises a first side gate portion 134a arranged along the first side surface 132a, a second side gate portion 134b arranged along the second side surface 132b, an upper gate portion 134c arranged along the upper surface 132c, and a lower gate portion 134d arranged along the lower surface 132d.

The top channel nanosheet 142 of the top device 140 is horizontally oriented, i.e. parallel to the substrate 102. The nanosheet 142 has a first side surface 142a oriented in the first horizontal direction (e.g. the X direction) and a second side surface 142b oriented in the opposite second horizontal direction (e.g. the −X direction). The nanosheet 142 further has an upper surface 142c oriented in an upward direction (e.g. the Z direction) and a lower surface 142d oriented in a downward direction (e.g. the −Z direction).

The top gate electrode 144 is configured to define a tri-gate with respect to the nanosheet 142. The top gate electrode 144 comprises an upper gate portion 144c arranged along the upper surface 142c, a lower gate portion 144d arranged along the lower surface 142d, and a side gate portion 144b arranged along the second side surface 142b. The upper gate portion 144c and the lower gate portion 144d each protrudes laterally/horizontally in the X direction from the side gate portion 144b, towards a respective free end.

The upper gate portion 144c and the lower gate portion 144d may hence be referred to as upper and lower gate prongs 144c, 144d, respectively.

The CFET device 100 further comprises a top gate contact via 146 and a bottom gate contact via 136 (shown in FIG. 2b). The top gate contact via 146 is provided for coupling the top gate electrode 144 to a first conductive line 124 over the top FET device 140. The bottom gate contact via 136 is provided for coupling the bottom gate electrode 134 to a second conductive line 128 over the top FET device 140. As will be further described herein, the first and second conductive lines 124, 128 may e.g. form part of an interconnect layer arranged over the top FET device 140. In particular the first and second conductive lines 124, 128 may be arranged along respective routing tracks of a circuit cell of an integrated circuit.

Due to the tri-gate configuration of top gate electrode 144, the top gate electrode 144 presents a zero-gate extension along the first side surface 142a of the top channel nanosheet 142, such that the first side surface 142a defines a non-gated side surface. Hence, while the top gate electrode 144 is arranged directly above the bottom gate electrode 134 such that the top gate electrode 144 partially overlaps the bottom gate electrode 134 (e.g. as viewed along the Z direction), the zero-gate extension allows the side gate portion 134a of the bottom gate electrode 134 to defines a via contact portion protruding outside the top gate electrode 144 and the (non-gated) first side surface 142a of the top channel nanosheet 142. The via contact portion defined by the side gate portion 134a is hence laterally offset or displaced (along the X direction) with respect to the top device 140, in particular with respect to the top channel nanosheet 142 and the top gate electrode 144. This creates a space for the bottom gate contact via 136 contacting the via contact portion 134a of the bottom gate electrode 134. The bottom gate contact via 136 may as shown extend in a top-down direction (e.g. −Z direction) past the non-gated first side surface 142a of the top channel nanosheet and the top gate electrode 140 and through the dielectric layer 150 to contact the via contact portion of the bottom gate electrode 134.

In FIG. 2b the free ends of the upper and lower gate portions 144c, 144d are schematically shown to be exactly aligned with the first side surface 142a of the top channel nanosheet 142. As may be appreciated, an exact alignment may in practice be difficult to achieve with a high yield (e.g. due to process variations) and is in any case not a requirement for creating the space for the bottom gate contact via 136. For instance, it is contemplated that depending on the particular process (see below discussion) used to define form the top gate electrode 144 trace amounts of gate material (e.g. gate work function metal and/or gate dielectric) may be present along or on the first side surface 142a. However, as would be understood by a skilled person it is expected that such trace amounts will not be sufficient to define a functional side gate portion along the first side surface 142a. Hence, even in such a case the top gate electrode 144 would be configured to function as a tri-gate with respect to the nanosheet 142.

In the illustrated embodiment, the bottom channel nanosheet 132 and the top channel nanosheet 142 have a same width (e.g. along the X direction). Furthermore, the top channel nanosheet 142 is arranged above the bottom channel nanostructure 132 such that the first side surface 132a of the bottom channel nanostructure 132 is aligned with the first side surface 142a of the top channel nanosheet 142 and the second side surface 132b of the bottom channel nanosheet 132 is aligned with the second side surface 142b of the top channel nanosheet 142. The top channel nanosheet 142 is hence arranged directly above the bottom channel nanosheet 132 such that the top channel nanosheet 142 overlaps the bottom channel nanosheet 132 completely, or at least substantially completely, as viewed along the Z direction. While such a configuration may contribute to an area efficient design as well as a uniform electric performance of the bottom and top device 130, 140, also other embodiments are envisaged. For instance, a CFET device comprising a bottom channel nanosheet and top channel nanosheet of different widths. For example, only the respective first side surfaces of the bottom and top channel nanosheets may be aligned. The top channel nanosheet may hence be arranged to only partially overlap the bottom channel nanosheet.

It is further contemplated that the bottom device 130 and/or the top device 140 may comprise a number of channel nanosheets, such as two or more channel nanosheets stacked above each other. This may enable an increased drive current although at a cost of an increased device height.

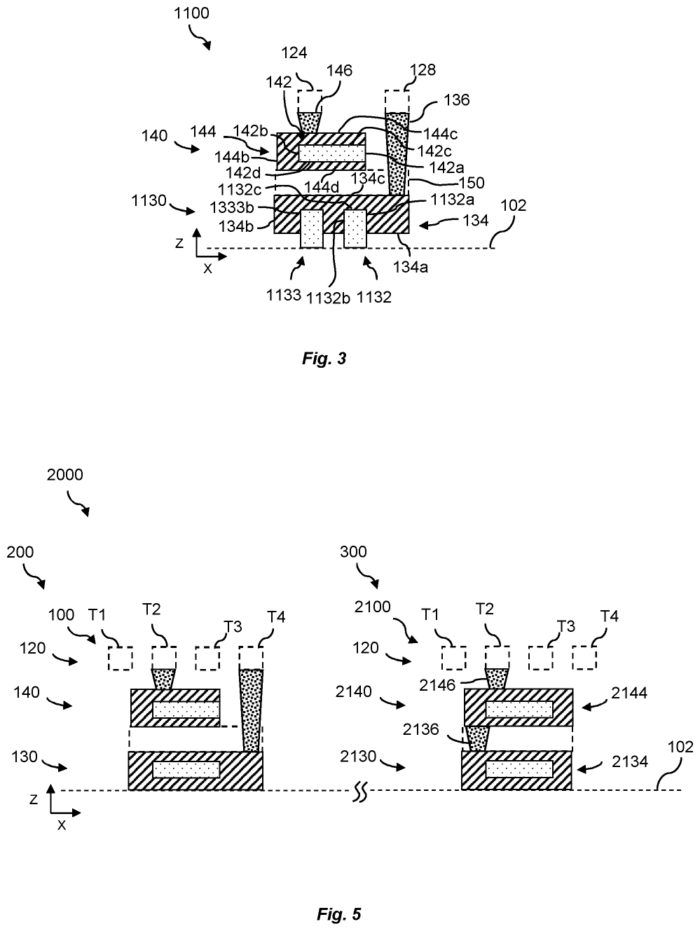

FIG. 3 depicts a CFET device 1100 according to a further embodiment. FIG. 3 is a cross-sectional view corresponding to the cross-section in FIG. 2b. The CFET device 1100 is similar to the CFET device 100 and differs only in that the bottom device 1130 comprises a pair of channel nanostructures in the form of a pair of a first and second semiconductor fin structure 1132, 1133, instead of the nanosheet 132. The second fin structure 1133 extends in parallel to the first fin structure 1132. The top channel nanosheet may as shown be arranged directly above each of the first and the second fin structure 1132, 1133, and thus overlap the same, as viewed along the Z direction.

The bottom gate electrode 134 extends across the first and second fin structures 1132, 1133 to define a tri-gate with respect to each of the fin structures 1132, 1134. More specifically, the side gate portion 134 of the bottom gate electrode 134 is arranged along a first side surface 1132a of the first fin structure 1132 and defines a via contact portion protruding outside the top gate electrode 144 and the (non-gated) first side surface 142a of the top channel nanosheet 142. As discussed above, this creates a space for the bottom gate contact via 136 to contact the via contact portion 134a of the bottom gate electrode 134.

Although FIG. 3 depicts a pair of fin structures 1132, 1134 it is possible to provide a bottom device 130 comprising only a single fin structure, or more than two fin structures. For instance, an increased width top channel nanosheet 142 and/or a tighter fin spacing may allow for accommodating three or more fin structures within the footprint of the top channel nanosheet 142.

The CFET devices 100 and 1100 may be sequential CFET devices, e.g. CFETs formed in a sequential process using techniques which per se are known in the art. By way of example, forming the bottom device 130, 1130 may comprise forming channel nanostructures by patterning a nanosheet or a stack of nanosheets (in the case of a nanosheet-based bottom device like bottom device 130) or a fin-shaped channel nanostructure (in the case of a fin-based bottom device like bottom device 1130) in one or more semiconductor layers; forming dummy gates across the channel nanostructures; defining source/drain regions on either side of the dummy gates by epitaxy and/or ion implantation; replacing the dummy gates with functional gates (e.g. comprising gate dielectric and gate metal). The bottom device 130, 1130 may subsequently be covered by a dielectric layer (e.g. layer 150) and any further interfacial layers e.g. to facilitate a subsequent bonding step. The top device 140 may then be formed by bonding a substrate on top of the bottom device 130, 1130 (e.g. comprising one or more semiconductor layers) and thereafter forming the top device 140 in a manner similar to the bottom device 130 (e.g. patterning a nanosheet or a stack of nanosheets in the one or more semiconductor channel layers, etc.). The tri-gate configuration of the top gate electrode 144 may be achieved e.g. by cutting away a portion of the dummy gate extending past the first side surface 142a of the top channel nanosheet 142 (e.g. using a dummy gate etch) and replace the removed portion with a block mask, prior to the gate replacement step. It is also possible to cut away a portion of the metal gate electrode extending past the first side surface 142a of the top channel nanosheet 142 (e.g. using a gate metal etch/cut), subsequent to a dummy gate replacement step. As per se is known in the art, if the channel nanostructure is a nanosheet (e.g. like in the bottom device 130 and the top device 140) the fabrication may further comprise a step of channel nanosheet release, performed as a sub-step within the replacement metal gate process, comprising removing sacrificial layers below and on top of the channel nanosheet to expose the upper and lower surfaces of the channel nanosheet ahead of the gate dielectric and gate metal deposition.

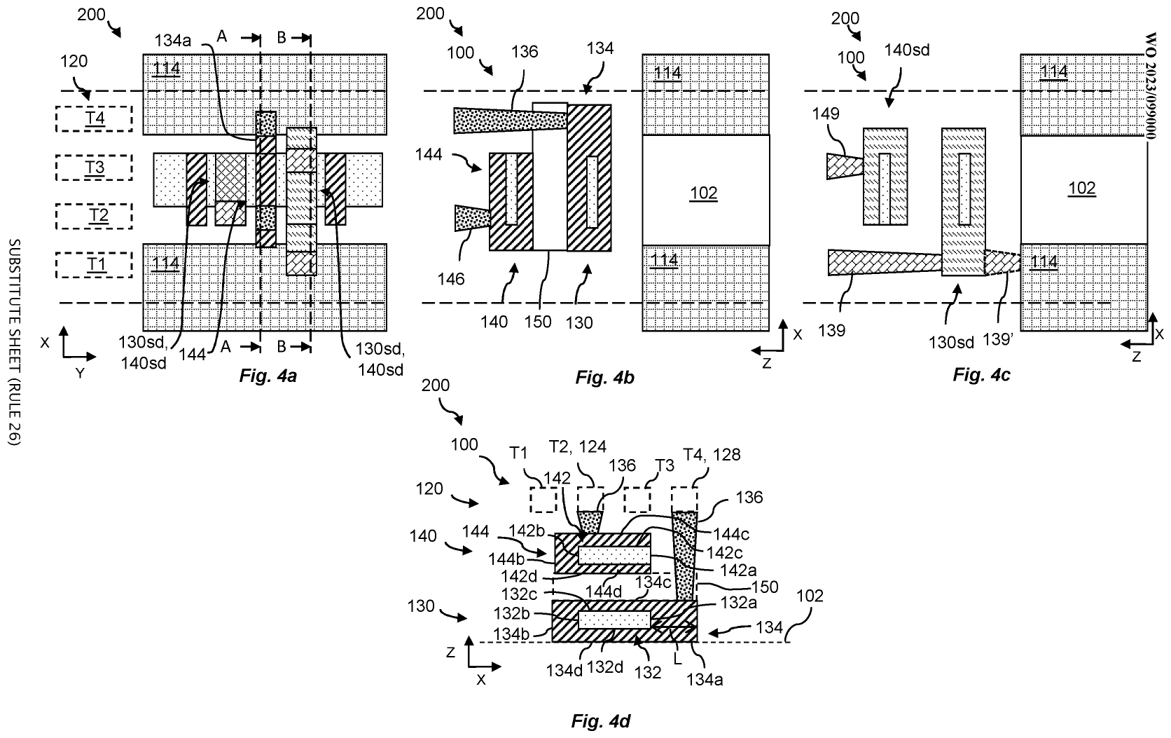

FIGS. 4a-d schematically illustrate an embodiment of a circuit cell 200 comprising the CFET device 100. Although the illustrated circuit cell 200 comprises the CFET device 100, it is equally possible to replace the CFET device 100 by the CFET device 1100. The views in FIGS. 4a-d generally correspond to those of FIGS. 1a-d. The circuit cell 200 comprises an interconnect layer 120 arranged over the top FET device 140 and comprising the first and the second conductive line 124, 128.

The circuit cell 200 is a 4T cell requiring electrically independent gates of the bottom and top device 130, 140, for example a sequential standard cell of a standard cell library, including a tri-state/transmission-gate subcircuit. The circuit cell 200 may however also implement some other functionality such as a memory cell.

The cell 200 comprises four routing tracks: two edge tracks T1, T4 and two non-edge or inner tracks T2, T3. The routing tracks T1-T4 are uniformly spaced apart along direction X and extend in parallel along direction Y. The dashed lines extending in the Y direction represent boundaries of the cell 200, along the cell height direction X.

The conductive line 124 is arranged to extend along track T2 which is arranged directly above the top gate electrode 144. The top gate contact via 146 extends vertically between the conductive line 124 and the top gate electrode 144 to electrically couple the conductive line 124 to the top gate electrode 144.

The conductive line 128 is arranged to extend along track T4 which is arranged directly above the via contact portion defined by the side gate portion 134a. In other words, the side gate portion 134a of the bottom gate electrode 134 protrudes in the X direction such that the via contact portion is positioned directly underneath track T4 and the conductive line 128. The bottom gate contact via 136 extends vertically between the conductive line 128 and the via contact portion to electrically couple the conductive line 128 to the bottom gate electrode 134.

As may be appreciated, the length of the gate extension of the bottom gate electrode 134, i.e. the via contact portion, along the X-direction (denoted L in FIG. 4d) may be in a range of 8-10 nm. A spacing of the routing tracks T1-T4 may be of a corresponding dimension. A gate extension of 8-10 nm corresponds approximately to 1 critical dimension (CD) for current gate cut processes and is compatible with the N2 technology node.

In the illustrated embodiment track T2 is arranged directly above the upper gate portion 144c of the top gate electrode 144. However, it is contemplated that track T2 also may be arranged directly above the side gate portion 144b. It is further contemplated that the top gate electrode 144 may be coupled to a conductive line of the interconnect layer 120 extending along the edge track T1, by extending the side gate portion 144b in the −X direction to a position directly underneath track T1. However, it may be advantageous to couple the top gate electrode 144 to a non-edge track in that the edge track T1 then may be used for power rails for the CFET device 100.

FIG. 4c depicts an example of signal routing to the respective source/drain regions 130sd, 140sd of the bottom and top devices 130, 140. The source/drain region 130sd of the bottom device 130 may as shown be coupled to a conductive line extending along track T1 while source/drain region 140sd of the top device 14 may be coupled to a conductive line extending along track T3 by vias 139 and 149, respectively. A corresponding signal routing may be implemented at the source/drain regions at the opposite sides of the channels. This however merely represents one of numerous examples for signal routing to the source/drain regions. For example, as further indicated in FIGS. 4a-c, buried power rails 114 may be embedded in the substrate 102. The buried power rails 114 may extend along the boundaries of the cell 200. The buried power rails 114 may provide additional routing resources without introducing further congestion in interconnect levels above the CFET device 100. For example, the via 139 coupled to the source/drain region 130sd may be replaced with a via (via 139′ indicated by dashed lines in FIG. 4c) coupled to a buried power rail 114. Additionally, or alternatively, the source/drain region 140sd of the top device 140 may be coupled to the buried power rail along the opposite boundary of the cell 200. The source drain regions 130sd, 140sd may also in some examples be electrically interconnected by a via extending between the top and bottom device 130, 140.

FIG. 5 schematically illustrate an embodiment of an integrated circuit comprising a plurality of first circuit cells corresponding to circuit cell 200 (or alternatively a circuit cell comprising CFET device 1100) and a plurality of second circuit cells 300 comprising a CFET device 2100 (e.g. a sequential CFET) comprising a bottom device 2130 and a top device 2140 wherein the bottom gate electrode 2134 of the bottom device 2130 is coupled to the top gate electrode 2144 of the top device 2140 by a gate contact via 2136. The top gate electrode 2144 is coupled to a conductive line arranged along a track, e.g. track T2, by a top gate contact via 2146. The bottom gate electrode 2134 and the top gate electrode 2144 are hence connected to a common conductive line, the bottom gate electrode 2134 being connected to the conductive line through the via 2146, the top gate electrode 2144 and the via 2136. In the illustrated embodiment, the bottom and top gate electrodes 2134, 2144 are each configured to define gate-all-around with respect to their respective channel nanosheets. However, it is also possible to configure the bottom and/or top gate electrodes as tri-gates. Additionally, the bottom device 2130 may be a fin-based device instead of a nanosheet-based device.

FIG. 5 shows only cross-sectional views of the respective circuit cells 200, 300 corresponding to the view in FIG. 4d (i.e. through the channels and gates) to highlight the different connection approaches for the bottom and top gate electrodes. The circuit cell 300 may otherwise have a layout similar to the circuit cell 200 as shown in FIGS. 4a-d. In any case, FIG. 5 illustrates that CFET based circuit cells with independent gate pick-up and electrically common gates may be combined in a same integrated circuit.

In the above the inventive concept has mainly been described with reference to a limited number of examples. However, as is readily appreciated by a person skilled in the art, other examples than the ones disclosed above are equally possible within the scope of the inventive concept, as defined by the appended claims.

1. A complementary field-effect transistor, CFET, device comprising:
a bottom FET device and a top FET device stacked on top of the bottom FET device,
the bottom FET device comprising a bottom channel nanostructure having a first side surface oriented in a first direction and a second side surface oriented in a second direction opposite the first direction, and a bottom gate electrode configured to define a tri-gate or a gate-all-around with respect to the bottom channel nanostructure, the bottom gate electrode comprising a side gate portion arranged along the first side surface of the bottom channel nanostructure, and
the top FET device comprising a top channel nanosheet having a first side surface oriented in the first direction and a second side surface oriented in the second direction, and a top gate electrode configured to define a tri-gate with respect to the top channel nanosheet and comprising an upper gate portion, a lower gate portion and a side gate portion arranged along the second side surface of the top channel nanosheet,
wherein the side gate portion of the bottom gate electrode defines a via contact portion protruding outside the top gate electrode and the first side surface of the top channel nanosheet, and
a top gate contact via for coupling the top gate electrode to a first conductive line over the top FET device and a bottom gate contact via for coupling the via contact portion of the bottom gate electrode to a second conductive line over the top FET device.

2. A device according to claim 1, further comprising a dielectric layer arranged between the bottom gate electrode and the top gate electrode, wherein the bottom gate contact via extends through the dielectric layer.

3. A device according to claim 1, wherein the top channel nanosheet is arranged directly above the bottom channel nanostructure.

4. A device according to claim 1, wherein the first side surface of the bottom channel nanostructure is aligned with the first side surface of the top channel nanosheet.

5. A device according to claim 1, wherein the bottom channel nanostructure is a nanosheet.

6. A device according to claim 5, wherein the bottom channel nanosheet and the top channel nanosheet have a same width.

7. A device according to claim 5, wherein the first side surface of the bottom channel nanosheet is aligned with the first side surface of the top channel nanosheet, and the second side surface of the bottom channel nanosheet is aligned with the second side surface of the top channel nanosheet.

8. A device according to 5, wherein the bottom gate electrode is configured to define a gate-all-around with respect to the bottom channel nanosheet.

9. A device according to claim 1, wherein the bottom channel nanostructure is a first fin structure, and wherein the bottom gate electrode extends across the first fin structure to define a tri-gate with respect to the first fin structure.

10. A device according to claim 9, wherein the bottom FET device further comprises a second fin structure arranged alongside the first fin structure, and wherein the bottom gate electrode extends across the first fin and second fin structures to define a tri-gate with respect to each of the first and second fin structures.

11. A device according to claim 10, wherein the top channel nanosheet is arranged directly above the first and the second fin structure.

12. A circuit cell comprising:
a CFET device according to claim 1; and
an interconnect layer arranged over the top FET device and comprising the first and the second conductive line,
wherein the first conductive line of the interconnect structure is arranged to extend along a first routing track of the circuit cell and the second conductive line of the interconnect structure is arranged to extend along a second routing track of the circuit cell, the first and second routing tracks extending in parallel along a third direction transverse to the first and second directions.

13. A circuit cell according to claim 12, wherein the circuit cell is a 4-track cell, the second routing track is an edge track, the first routing track is located directly above the top gate electrode, and wherein the side gate portion of the bottom gate electrode protrudes in the first direction such that the via contact portion is positioned directly underneath the first edge track.

14. A circuit cell according to claim 13, wherein the first routing track is a non-edge track arranged directly above the bottom and top gate electrode.

15. An integrated circuit comprising:
a plurality of first circuit cells each in accordance with claim 12; and
a plurality of second circuit cells each comprising a bottom FET device and a top FET device stacked on top of the bottom FET device, the bottom FET device comprising a bottom channel nanostructure and a bottom gate electrode configured to define a tri-gate or a gate-all-around with respect to the bottom channel nanostructure, and
the top FET device comprising a top channel nanostructure and a top gate electrode configured to define a tri-gate or a gate-all-around with respect to the top channel nanostructure,
a bottom gate contact extending between the top gate electrode and the bottom gate electrode to couple the top gate electrode to the bottom gate electrode, and
a top gate contact via coupling the top gate electrode to a third conductive line.
